(19) United States
(12) Patent Application Publication
(10) Pub. No.: US 2006/0092749 A1
(43) Pub. Date: May 4, 2006

(54) Bitline layout in a dual port memory array

(75) Inventor: Tak Kwong Wong, Milpitas, CA (US)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Integrated Device Technology, Inc.

(21) Appl. No.: 10/976,642

(22) Filed: Oct. 29, 2004

(51) Int. Cl. G11C 8/00

(52) U.S. Cl. 365/230.05

(57) ABSTRACT

A multi-port memory array according to some embodiments of the present invention includes a first complementary pair of bit lines of length L corresponding to a first port; a second complementary pair of bit lines of length L corresponding to a second port, wherein the first complementary pair of bit lines is interleaved with the second complementary pair of bit lines, and wherein the first complementary pair of bit lines is twisted at L/2 and the second complementary pair of bit lines is twisted at L/4 and 3L/4. The capacitive coupling between a bit line of the first complementary pair of bit lines and each of the bit lines of the second complementary pair of bit lines is therefore the same, resulting in an elimination of the effects of capacitive coupling.

### BACKGROUND

1. Field of the Invention

The present invention is related to multi-port memory systems and, in particular, to a bit line layout for multi-port memory systems.

2. Background of the Invention

Multi-port memory systems (e.g., dual port memory systems) are utilized in many modern multi-processor computing systems and telecommunications systems. However, traditional dual-port memory cell layouts suffer from bit-line capacitive coupling in the same port and bit-line capacitive coupling between ports. Such capacitive coupling results in dramatic slow down in data transfer speeds in the bit lines. Further, capacitive coupling can result in corruption of data on some bit lines from data being transmitted on neighboring bit lines.

Traditional memory cells suffer from bitline to complementary bitline capacitive coupling during memory read. The bitline reading of one, for example, will be dragged down by the neighboring bitline's reading a zero. Therefore, the time to achieve a differential voltage is increased. As a result, there is a longer delay for a sense amp coupled to the bitline and its complement to output valid data.

FIG. 1 illustrates a dual port memory array 100. Typically, memory array 100 includes an array of individual cells 101. Word lines 107 associated with each of the ports are coupled to each of individual cells 101 along a row. Bit lines 102 that couple data to each of individual cells 102 are coupled to each of individual cells 101 along columns. Data is read or written from a target cell of individual cells 101 by activating a row of cells that contain the target cell with a word line 107. If the cell is to be accessed from port A, then the word line associated with port A is activated. If the cell is to be accessed from port B, then the word line associated with port B is activated. Appropriate data is then read from or applied to the bit lines associated with port A or port B.

As shown in FIG. 1, bit lines 102 are coupled to sense amps or controllers 103 and 104. Controller 103 couples data applied to port A to appropriate bit lines 102 that correspond to port A. Controller 104 couples data applied to port B to appropriate bit lines 102 associated with port B. Addresses are applied to controllers 106 and 105 for port A and port B, respectively, and appropriate word lines 107 are activated.

As a result, bit lines for each column are often run in close proximity to other bit lines. As a result, each of bit lines 102 suffers significant capacitive coupling to neighboring bit lines. In some cases, a power or ground line is run between bit lines from the two ports in order to shield the bit lines of one port from the bit lines of another. This often results in memory arrays that are larger in size than they would be without the need for shield lines.

Therefore, there is a need to reduce or eliminate the effects from capacitive coupling between individual bit lines.

### SUMMARY

In accordance with the present invention, bit lines are arranged symmetrically such that the effects of capacitive coupling between any pair of neighboring bit lines is eliminated. In some embodiments, where bit lines are formed in a single metallization, a complementary pair of bit lines of a first port are interleaved with a complementary pair of bit lines of a second port and each of the complementary pairs are twisted such that each individual bit line of the first port has the same capacitive coupling to each individual bit line of the second port.

A multi-port memory array according to some embodiments of the present invention includes a first complementary pair of bit lines of length L corresponding to a first port; a second complementary pair of bit lines of length L corresponding to a second port, wherein the first complementary pair of bit lines is interleaved with the second complementary pair of bit lines, and wherein the first complementary pair of bit lines is twisted at L/2 and the second complementary pair of bit lines is twisted at L/4 and 3L/4. Memory cells can be coupled to the first complementary pair of bit lines and the second complementary pair of bit lines. In some embodiments, the memory cells are arranged to accommodate the layout of bit lines. In some embodiments, a DC offset compensation circuit coupled between the first complementary pair of bit lines and the second complementary pair of bit lines.

A method of reducing the effects of capacitive coupling between complementary pairs of bit lines according to the present invention includes interleaving a first complementary pair of bit lines with a second complementary pair of bit lines; twisting the first complementary pair of bit lines at a ½ L position; and twisting the second complementary pair of bit lines at a ¼ L position and a ¾ L position. In some embodiments, memory cells are coupled to the first complementary pair of bit lines and the second complementary pair of bit lines. In some embodiments, some of the memory cells to the first complementary pair of bit lines and the second complementary pair of bit lines are coupled through an inverter. In some embodiments, a DC offset compensation circuit between the first complementary pair of bit lines and the second complementary pair of bit lines is provided.

It is to be understood that both the foregoing general description and the following detailed description are exemplary and explanatory only and are not restrictive of the invention, as claimed. These and other embodiments are further discussed below with respect to the following figures.

### BRIEF DESCRIPTION OF THE DRAWINGS

FIG. 1 illustrates a dual port memory array.

FIG. 2 illustrates a bit line layout according to the present invention.

FIG. 3A illustrates a bit line layout according to the present invention for an odd number of ports.

FIG. 3B illustrates a bit line layout according to the present invention for an even number of ports.

FIG. 3C illustrates a bit line layout according to the present invention for bit lines deposited in two metallizations.

FIGS. 4 illustrates the layout of memory cells that can be utilized in the bit line layout according to the present invention shown in FIG. 2.

FIG. 5 illustrates a bit line inversion circuit according some embodiments of the present invention.

FIGS. 6A and 6B illustrate a DC compensation circuit according to some embodiments of the present invention.

In the figures, elements having the same reference numbers have the same or similar functions.

### DESCRIPTION OF THE EMBODIMENTS

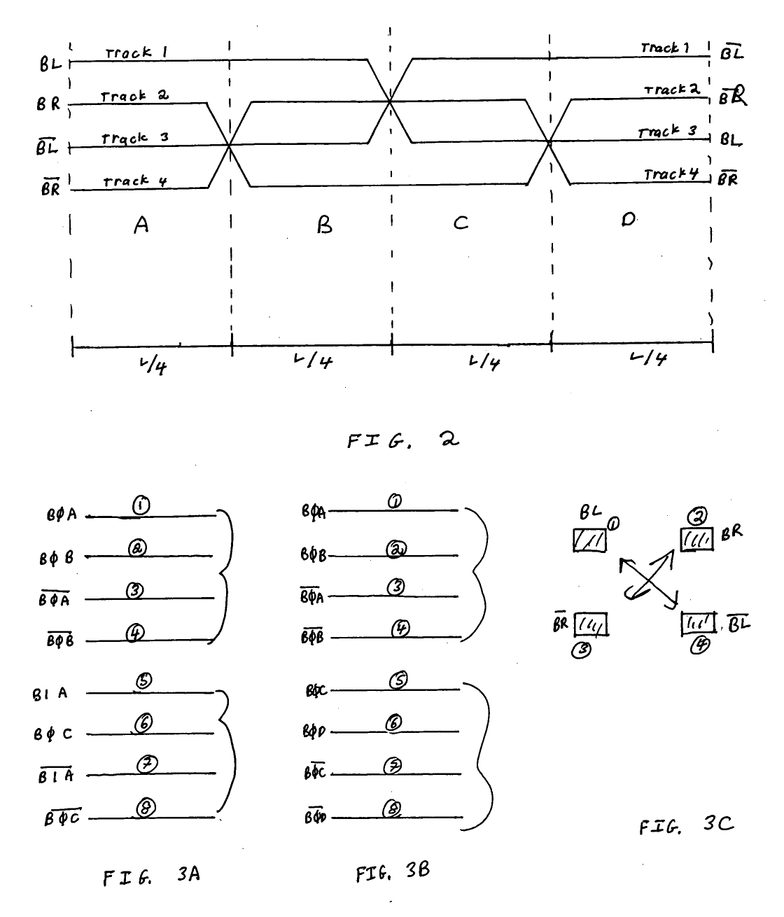

FIG. 2 illustrates a bit line layout in a dual-port memory system according to some embodiments of the present invention. As illustrated in FIG. 2, a complementary pair of bit lines from the left port BL and \overline{BL} and a complementary pair of bit lines from the right port BR and \overline{BR} are interleaved (i.e., a bit line from the complimentary pair for the left port is located between the complementary pair of bit lines for the right port). FIG. 2 illustrates the bit line layout in a single metallization layer for one column of memory cells in the memory array. On the left, complementary pair of bit lines BL and \overline{BL} are interleaved with BR and \overline{BR} so that the order of bit lines on the left side is BL, BR, \overline{BL}, and \overline{BR}. As shown in FIG. 2, the bit lines have a length L in the memory array. Bit lines BL and \overline{BL} are twisted at L/2 (i.e., the two bit lines swap locations in the bit line layout). Further, as shown in FIG. 2, bit lines BR and \overline{BR} are twisted at L/4 and 3L/4.

As shown in FIG. 2, the capacitive coupling between BL and \overline{BL}, and the capacitive coupling between BR and \overline{BR} are negligible due to shielding from the interleaved bit line between them. In some embodiments, when a bit line and its complements cross during a twist, the interaction is still small enough to be negligible. The capacitive coupling between BL and BR and the capacitive coupling between BL and \overline{BR} in the bit line layout shown in FIG. 2 are then the same. Further, the capacitive coupling between \overline{BL} and BR and the capacitive coupling between \overline{BL} and \overline{BR} in the bit line layout of FIG. 2 are the same.

In FIG. 2, the bit lines are physically positioned along tracks, labeled tracks 1 to 4, from top to bottom. Because the geometrical relationship between any two tracks is the same throughout the memory array, the coupling capacitance per unit length between any pair of tracks in each of the areas A, B, C, or D is substantially identical. Assuming that the capacitive coupling per unit length between two arbitrary adjacent tracks, tracks p and q, is given by Cpq/(L/4), then the capacitive coupling between BL and BR, the capacitive coupling between BL and \overline{BR}, the capacitive coupling between \overline{BL} and BR and the capacitive coupling between \overline{BL} and \overline{BR} are all C₁₂+C₂₃+C₃₄. From this symmetry, any change in voltage on any bitline of one port will couple equally to the bitline and complementary bitline of the other port. Therefore, the differential voltage between the bit line and its complement will not be affected by the capacitive coupling because the coupling appears as a DC-offset in the complementary pair of bit lines instead of affecting each bit line separately.

The twisting of bitlines shown in FIG. 2 has the benefit of averaging out the geometrical and coupling capacitance difference between different physical tracks (e.g., tracks 1-4 shown in FIG. 2). The delay in reading the data, then, is no longer polarity dependent. The elimination of the effect of capacitive coupling, therefore, results in faster determination of the data carried between a bit line and its complement. Further, the effects of capacitive coupling are removed without placing a power or ground line along the bit lines to shield bit lines from the two ports. Smaller memory cell size and therefore small memory arrays can be achieved.

FIG. 2 illustrates a bit line layout according to the present invention in a dual port memory array. However, embodiments of the present invention can be utilized in a memory array having any number of ports. FIGS. 3A and 3B illustrate bit line layouts for three and four port memory arrays, respectively. One of ordinary skill in the art will recognize from the embodiments illustrated in FIGS. 3A and 3B, embodiments of line layouts according to the present invention for any arbitrary number of ports.

FIG. 3A illustrates an embodiment of bit line layout for a three-port memory array with ports A, B, and C. As is seen in FIG. 3A, bit 0 of ports A and B are interleaved and twisted in tracks 1-4. The intertwining and twisting can be the same as illustrated in FIG. 2 for left and right port bit lines. Further, bit 1 of port A and bit 0 of port C are interleaved and twisted in tracks 5-8. In a third set (not shown), bit 1 of port B and bit 1 of port C are interleaved and twisted. As such, all of the bit lines from ports A, B, and C are interleaved with one another and twisted according to the present invention so as to achieve the symmetries in capacitive coupling that were discussed with respect to FIG. 2. FIGS. 3A and 3B illustrate the interleaving and twist shown in portion A of the two-port example shown in FIG. 2. Twists can occur in a pair of interleaved and twisted lines as shown in FIG. 2, at L/4, L/2, and 3L/4. The coupling capacitance between the bitlines of bit 0 of port A and the bitlines of bit 0 of port B is, then, C₁₂+C₂₃+C₃₄. The coupling capacitance between bit 1 of port A and bit 0 of port C is C₅₇+C₅₈+C₈₉. Further, the coupling capacitance between bit 1 of port A and bit 1 of port C is C_{10,11}+C_{11,12}+C_{12,13}.

FIG. 3B illustrates an embodiment of line layout for a four port memory array with ports A, B, C, and D. As seen in FIG. 3B, which only shows a section equivalent to section A of FIG. 2, bitlines corresponding to bits from ports A and B are interleaved and twisted in tracks 1-4 as illustrated in FIG. 2. Further, bitlines corresponding to bits from ports C and D are interleaved and twisted in tracks 5-8. As such, bitlines from ports A and B are interleaved and twisted and bitlines from ports C and D are interleaved and twisted. The coupling capacitance between bitlines of port A and bit lines of port B is C₁₂+C₂₃+C₃₄ The coupling capacitance between bitlines of port C bitlines of port D is C₅₆+C₆₇+C₇₈. The coupling capacitance between bitlines of port B and bitlines of port C is C₄₅. The coupling capacitance between bitlines of other ports are negligible due to shielding. In some embodiments, a ground or power line may be routed between tracks 4 and 5 so that the capacitive coupling between tracks 4 and 5 becomes 0.

FIG. 3C illustrates a bitline layout according to the present invention in a memory array that utilizes two metallization layers. As shown, lines BL and BR start on an upper mettalization layer and lines \overline{BL} and \overline{BR} start on a lower metallization layer. Twisting occurs as is illustrated in FIG. 2 with the twisting occurring between the two metallization layers rather than in a single metallization layer.

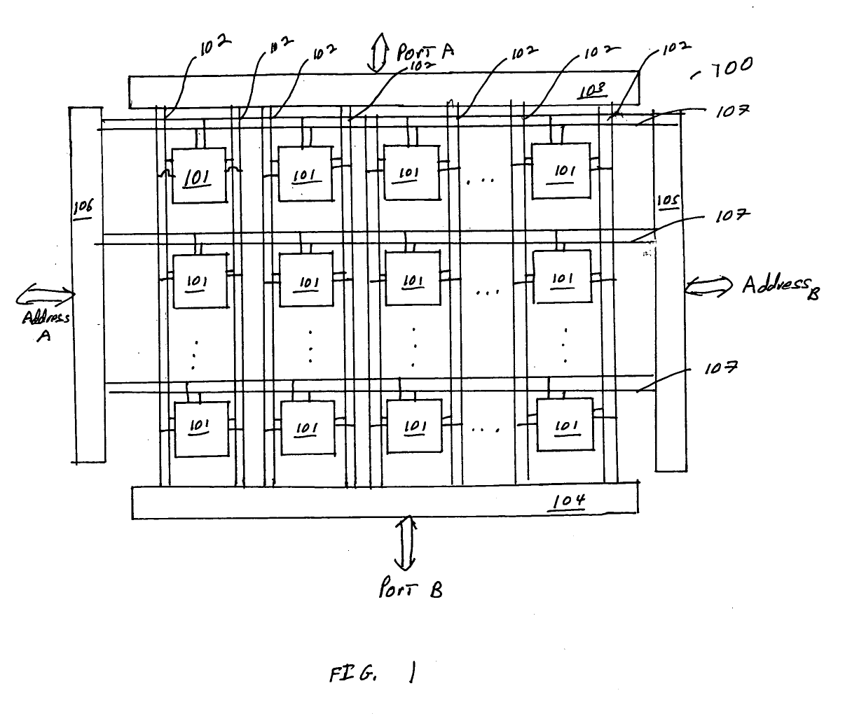

With reference again to FIG. 2, bit lines run throughout a memory array. Therefore, memory cells are constructed between complementary pairs of bit lines as is illustrated in FIG. 1. As is shown in FIG. 2, there are therefore four areas of bit line, areas A, B, C, and D. In some embodiments of the invention, individual memory cells are arranged appropriately for the particular bit-line configuration in each area.

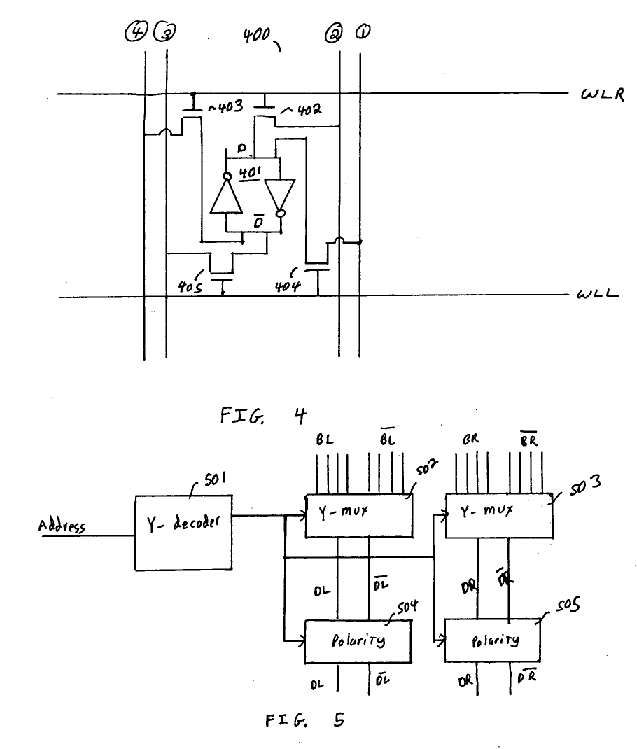

FIG. 4 illustrates a memory cell 400 according to some embodiments of the present invention. As is illustrated in FIG. 4, memory cell 400 includes a storage circuit 401 and transistors 402, 403, 404, and 405. Transistors 402 and 403 have gates coupled to the word line for the right port WLR to allow access to the memory cell from the right port. Transistors 404 and 405 have gates coupled to the word line for the left port WLL to allow access to the memory cell from the left port. As shown in FIG. 4, the bit lines, right to left, correspond to tracks 1 through 4, as shown in FIG. 2. Transistor 402 couples the data side D of storage circuit 401 to track 2 while transistor 403 couples the complementary data side \overline{D} of storage circuit 401 to track 4. Similarly, transistor 404 couples the data side D of storage cell 401 to track 1 while transistor 405 couples the complementary data side \overline{D} to track 3.

The embodiment of memory cell shown in FIG. 4 is a departure from that utilized in conventional cells because, in conventional cells, tracks 1 and 2 would be bit lines BL and \overline{BL} while tracks 3 and 4 would be bit lines BR and \overline{BR}. In FIG. 4, tracks 1-4 carry bit lines BL, BR, \overline{BL}, and \overline{BR}, respectively, in area A of FIG. 2, carry bit lines BL, \overline{BR}, \overline{BL}, and BR, respectively, in area B, carry bit lines \overline{BL}, \overline{BR}, BL, and BR, respectively, in area C, and carry bit lines \overline{BL}, BR, BL, and \overline{BR}, respectively, in area D.

In some embodiments of the invention, the layout of memory cell 400 as shown in FIG. 4 can be utilized in each of areas A, B, C, and D of the bit line layout shown in FIG. 2. However, in those embodiments care must be taken to insure that the correct polarity of data is written into storage cell 401, or read from storage cell 401. For example, in area B of the bit line layout shown in FIG. 2, bit lines BR and \overline{BR} have been switched but bit lines BL and \overline{BL} have not. Therefore, if data is written into cell 400 from the right port, it will be inverted with respect to the same data written in from the left port. Therefore, in embodiments that utilize the layout of memory cell 400 as shown in FIG. 4A for area B as well as area D, inverters can be coupled to the data input path and the data output path in either the left port or the right port so that data is written into memory cell 400 from either the right or left port is read by the opposite port in the same sense. The inversion of data depends on only I bit of address which select either area A,C or area B,D. The inversion, therefore, can be achieved by a simple Data XOR Address logic.

FIG. 5 illustrates a circuit for inverting the polarity of data lines as suggested above. As shown in FIG. 5, an address, which can be 3-bit address, is received in Y-Decode block 501. The address is decoded and a particular row of bit lines is then selected. Data lines corresponding to data received in the memory system is received in left and right multiplexers 502 and 503, respectively. Multiplexers 502 and 503 provide data or read data to particular ones of the complementary pair of bit lines BL and \overline{BL} in multiplexer 502 and BR and \overline{BR} in multiplexer 503. In accordance with the present invention, a polarity block 504 can be coupled to multiplexer 502 so that the polarity of data lines DL and \overline{DL} can be inverted, depending on whether the memory cell is located in area A, B, C, or D as shown in FIG. 2. Similarly, in some embodiments a polarity block 505 can be coupled to multiplexer 503 so that data lines DR and \overline{DR} can be inverted depending on whether the memory cell is located in area A, B, C, or D. In some embodiments, the polarity of the right port data lines DR and \overline{DR} can be inverted in when the address indicates a memory cell in areas B and D. In some embodiments, the left port data lines DL and \overline{DL} are inverted when the address indicates a memory cell in areas B and D instead.

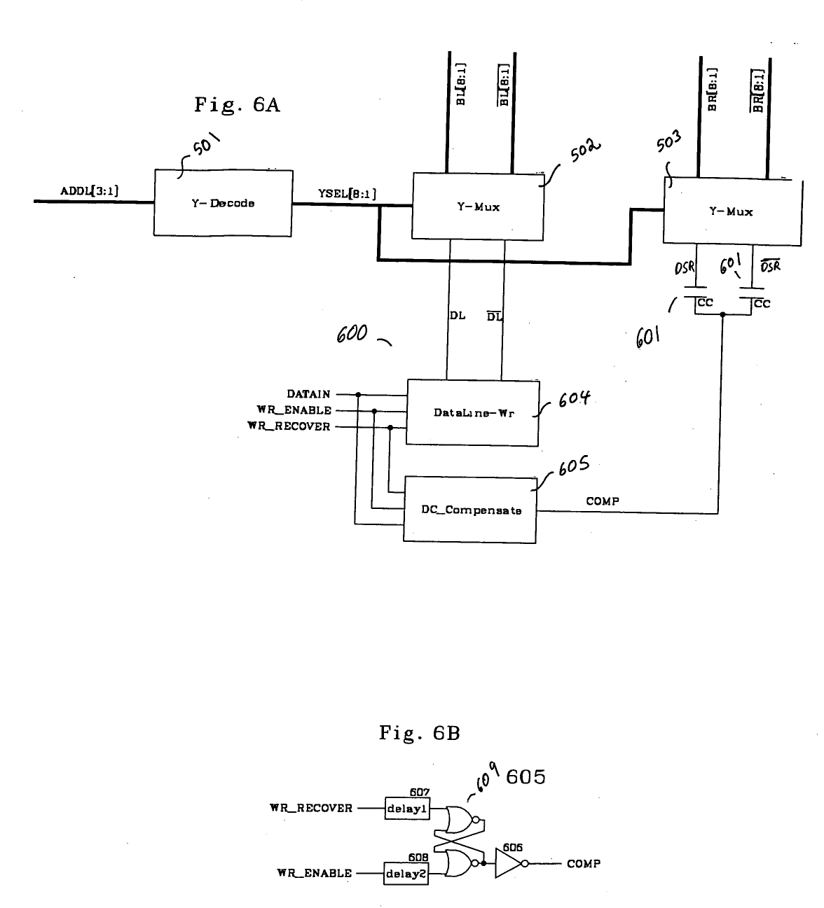

As a result of the capacitive coupling between bit lines from different ports, there is a DC offset in the bit lines of the opposite port. In some cases, the sense amplifier's common mode rejection may not be good enough to handle the DC offset, especially if the opposite port is writing data. FIG. 6A illustrates a DC offset compensation circuit 600 according to some embodiments of the present invention. When writing data to one port, the bit lines of the opposite port can be capacitively coupled with opposite polarity to nullify the DC offset. The output signal of compensation circuit 600 should match the bitline switching time & slew rate in order to have zero DC offset all the time.

As shown in FIG. 6A, data and a write enable and write recover signal are input to data line block 604. Note that, as shown in FIG. 6A and in FIG. 5, multiplexer 503 is controlled by the left-port address input to Y-decoder 501. Data line block 604 provides data lines DL and \overline{DL} to multiplexer 502. The data, write enable, and write recover signals are also input into DC compensate block 605, which produces a compensation signal COMP. The compensation signal COMP is then capacitively coupled through capacitors 601 to the pseudo data lines DSR and \overline{DSR} that are coupled into multiplexer 503. Similarly, a second compensation circuit would be coupled to the data lines DSL and \overline{DSL} to adjust for dc-offset in the left port from write operations occurring in the right port.

The signal COMP produced by DC compensation 605 switches in opposite polarity with respect to data lines DL and \overline{DL}. In some embodiments, each of capacitors 601 has capacitance CC equal to the coupling capacity felt between coupled lines, C₁₂+C₂₃+C₃₄ as discussed above. In compensation circuit 600, whenever the left port is performing a write with the bit lines, the bit lines of the right in the same column are being driven to offset the DC offset. The accuracy of the capacitance value for capacitors 601 is not critical; as minor DC offset is acceptable for sensing. A similar DC offset compensation circuit is need between all the writing ports and reading ports with bitline coupling. For example, six DC compensation circuits are included in a 4-port memory system as shown in FIG. 3B. A dual port system, for example, can include two DC compensation circuits such as that illustrated in FIG. 6A.

FIG. 6B illustrates an embodiment of compensation circuit 605 shown in FIG. 6A. As shown in FIG. 6B, a WR_ENABLE signals is input to delay 608 and a WR_RECPVER signal is input to delay 607. The output signals from delays 607 and 608 are input to a cross-latch NOR component 609. The output signal from cross-latch NOR component 609 is input to an inverter 606, which produces the compensation signal COMP.

In a typical synchronous SRAM, bitlines are precharged to one before read or write operation. In a write operation to the left port, either data line DL or data line \overline{DL} are pulled to 0 and then a write recovery operation occurs where both data line DL and data line \overline{DL} pulled back to 1. In such case, compensation circuit 605 can be implemented as shown in FIG. 6B. As shown in FIG. 6B, compensation circuit 605 is independent of the polarity of the DATAIN signal. When the WR_ENABLE signal is activated, one of the datalines DL or \overline{DL} will be pulled low. The COMP signal will be pulled high per the cross-latch NOR component 609 in circuit 605. A delay element 608 can be adjusted to achieve simultaneous switching of the COMP signal and switching of the dataline DL and \overline{DL} triggered by the WR_ENABLE signal. After the write operation, the WR_RECOVER signal switches to a 1, which pull back one of the datalines DL or \overline{DL} to a 1. The COMP signal will then be pulled low per the cross-latch NOR in circuit 605. The delay element 607 can be adjusted to achieve simultaneous switching of the COMP signal and the switching of data lines DL and \overline{DL} triggered by the WR_RECOVER signal. The driver 606 for COMP is adjusted so that the slew rate of COMP will be the same as that of dataline in both riseing and falling polarity shifts during write cycles.

Extra capacitors 601, however, add to the total capacitance of the bitlines and therefore contribute to delay on reads, the benefit of a bit line layout according to some embodiments of the present invention may be diminished. In accordance with some embodiments of the present invention, capacitor 601 can be achieved by placing a DC isolation metalization next to tracks 1 and 4 (see FIG. 2) and driving the DC isolation metalization with DC compensation circuit 605. The cost of applying one extra track per each four tracks is offset by the benefit of a DC compensation without the extra bitline capacitance.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A multi-port memory array, comprising:
a first complementary pair of bit lines of length L corresponding to a first port;
a second complementary pair of bit lines of length L corresponding to a second port,
wherein the first complementary pair of bit lines is interleaved with the second complementary pair of bit lines, and
wherein the first complementary pair of bit lines is twisted at L/2 and the second complementary pair of bit lines is twisted at L/4 and 3L/4.

2. The array of claim 1, further including memory cells coupled to the first complementary pair of bit lines and the second complementary pair of bit lines.

3. The array of claim 2, wherein the memory cells are arranged to accommodate the layout of bit lines.

4. The array of claim 1, further including a DC offset compensation circuit coupled between data lines of the multi-port memory array.

5. The array of claim 4, wherein the DC offset compensation circuit includes a fifth bitline.

6. The array of claim 1, further including an inverter circuit coupled between data lines of the multi-port memory array.

7. The array of claim 6, wherein a polarity of at least one data line is switched in response to a determination of where an accessed memory cell is located.

8. A method of reducing the effects of capacitive coupling between complementary pairs of bit lines, comprising:
interleaving a first complementary pair of bit lines of length L corresponding to a first port with a second complementary pair of bit lines of length L corresponding to a second port;
twisting the first complementary pair of bit lines at a ½ L position; and
twisting the second complementary pair of bit lines at a ¼ L position and a ¾ L position.

9. The method of claim 8, further including providing memory cells coupled to the first complementary pair of bit lines and the second complementary pair of bit lines.

10. The method of claim 8, further including providing a DC offset compensation circuit.

11. The method of claim 8, further including adjusting the polarity of signals on either the first complementary pair of bit lines or the second complementary pair of bit lines depending on a location of an accessed memory cell.

12. The array of claim 2, wherein at least one memory cell is coupled to both the first complementary pair of bit lines and the second complementary pair of bit lines.

13. The method of claim 9, further including at least one memory cell coupled to both the first complementary pair of bit lines and the second complementary pair of bit lines.
